(19) United States
(12) Patent Application Publication
(10) Pub. No.: US 2026/0095138 A1
(43) Pub. Date: Apr. 2, 2026

(54) BUZZER DRIVING SYSTEM AND METHOD THEREOF

(71) Applicant: NUVOTON TECHNOLOGY CORPORATION, HSINCHU CITY (TW)

(72) Inventor: Pao-Shu CHANG, Zhubei City (TW)

(21) Appl. No.: 19/335,688

(22) Filed: Sep. 22, 2025

Related U.S. Application Data
(60) Provisional application No. 63/701,378, filed on Sep. 30, 2024.

(30) Foreign Application Priority Data
Jan. 24, 2025 (TW) 114103530

(51) Int. Cl. H03G 3/30; G10K 9/122

(52) U.S. Cl. CPC H03G 3/3005; G10K 9/122; H03G 2201/103

(57) ABSTRACT

A buzzer driving system is electrically connected to a buzzer and includes a driving unit, a boost unit, and a gain estimation unit. The driving unit includes a gain control circuit that adjusts the gain of an audio signal based on a gain factor and outputs a driving voltage to the buzzer based on the adjusted audio signal. The boost unit is electrically connected to the driving unit and boosts an input voltage to generate a working voltage for the driving unit. The gain estimation unit is electrically connected to both the driving unit and the boost unit and is configured to generate a plurality of stepwise voltages based on the working voltage. The gain estimation unit sequentially compares the input voltage with each of the stepwise voltages to generate an estimated gain. The gain factor used by the gain control circuit is determined based on this estimated gain.

### CROSS-REFERENCE TO RELATED APPLICATION

This application claims priority to U.S. Provisional Patent Application No. 63/701,378, filed on Sep. 30, 2024, and Taiwanese Patent Application No. 114103530, filed on Jan. 24, 2025. The entire contents of both applications are incorporated herein by reference.

### BACKGROUND

### Technical Field

The present invention relates to a buzzer driving system and a method thereof, and more particularly to a buzzer driving system and method capable of detecting a boost ratio of a working voltage and adjusting the amplification gain of an audio signal accordingly.

### Description of Related Art

Buzzers are sound-generating components that are widely used in products such as alarms, multimedia devices, automotive electronic equipment, and toys. Buzzers are generally categorized into piezoelectric type and electromagnetic type. When the buzzer is powered, a metal diaphragm inside the buzzer vibrates within a resonance chamber to produce sound.

Conventional buzzers are mainly driven by digital signals, and therefore most buzzers can only produce a single tone. In addition, sound details are often filtered out by the buzzer, resulting in poor output sound quality that cannot compare with that of a speaker. Nevertheless, compared with speakers, buzzers still possess irreplaceable advantages such as compact size, high volume output, low cost, and durability.

On the other hand, for a buzzer to produce sufficiently loud sound, it is necessary to connect a voltage booster to increase the input voltage, thereby raising the voltage output to the buzzer. However, since conventional buzzers are driven by digital signals and their equivalent circuits can be regarded as a capacitor, short pulses in the digital signal are easily filtered out, resulting in the loss of sound details. Moreover, if an automatic gain control (AGC) is used to directly control the gain of the audio signal, it may easily cause distortion in the signal waveform.

### SUMMARY

Accordingly, how to resolve the aforementioned issues associated with buzzers has become one of the key challenges for those skilled in the art.

In view of the foregoing, an aspect of the present invention is to provide a buzzer driving system and method capable of detecting a boost ratio of a working voltage to adjust the amplification gain of an audio signal. This helps to preserve sound quality while increasing the buzzer volume, allowing the buzzer to reproduce sound details embedded in the audio signal. Additionally, the automatic detection of the boost ratio enables the system to adapt to variations in input voltage levels.

To achieve the foregoing aspect, a buzzer driving system comprises a driving unit, a boost unit, and a gain estimation unit, according to an embodiment of the present invention. The driving unit adjusts the gain of an audio signal through a gain control circuit with a gain factor, and outputs a driving voltage to the buzzer based on the audio signal. The boost unit is electrically connected to the driving unit and boosts an input voltage to generate a working voltage for the driving unit. The gain estimation unit is electrically connected to both the driving unit and the boost unit and is configured to generate a plurality of stepwise voltages based on the working voltage. The gain estimation unit sequentially compares the input voltage with each of the stepwise voltages to generate an estimated gain. The gain factor of the gain control circuit is set based on the estimated gain.

In line with the aspect of the present invention, a buzzer driving method is further provided according to another embodiment of this invention. The method comprises determining whether an input voltage has been boosted to a working voltage; when it is determined that the input voltage has been boosted to the working voltage, sequentially comparing the input voltage with a plurality of stepwise voltages to generate an estimated gain; setting a gain factor based on the estimated gain; adjusting the gain of an audio signal based on the gain factor; and outputting a driving voltage to the buzzer based on the audio signal.

Compared with conventional means for driving a buzzer and increasing its sound volume, the buzzer driving system and method above are capable of generating the driving voltage based on the audio signal in either analog or digital form. As such, the operation of the buzzer is not limited by the format of the input signal. In addition, the system can adapt to variations in the input voltage through an automatic detection mechanism of the boost ratio, thereby adjusting the gain factor of the audio signal accordingly. The driving unit then adjusts the gain of the audio signal based on the gain factor to enhance the sound volume of the buzzer, while simultaneously preventing signal distortion, so that the original details of the audio signal can be preserved and the sound quality improved.

### BRIEF DESCRIPTION OF THE DRAWINGS

FIG. 1 is a block diagram of a buzzer driving system according to an embodiment of the present invention.

FIG. 2 is another block diagram of a buzzer driving system according to another embodiment of the present invention.

FIG. 3 is a schematic diagram of a gain control circuit in the buzzer driving system according to an embodiment of the present invention.

FIG. 4 is a schematic diagram of a gain estimation unit in the buzzer driving system according to an embodiment of the present invention.

FIG. 5 is a flowchart of a buzzer driving method according to an embodiment of the present invention.

FIG. 6 is another schematic diagram of the gain estimation unit in the buzzer driving system according to another embodiment of the present invention.

### DETAILED DESCRIPTION

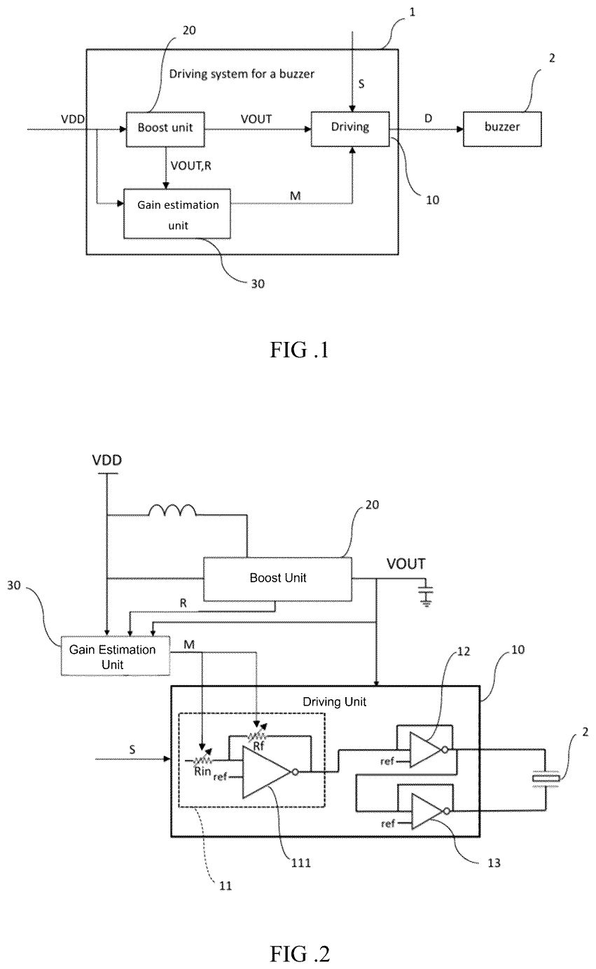

Referring to FIG. 1, a primary aspect of the present invention is to provide a buzzer driving system 1 capable of detecting the boost ratio of a working voltage VOUT and adjusting the gain factor of an audio signal S accordingly, thereby increasing the sound volume of a buzzer 2 while maintaining sound quality. The following provides a detailed description of possible embodiments of the present invention with reference to the drawings. It should be noted, however, that the following details are not intended to limit the scope of the claimed invention, but are provided for the purpose of facilitating understanding by those skilled in the art.

The buzzer driving system 1 is electrically connected to a buzzer 2 and comprises a driving unit 10, a boost unit 20, and a gain estimation unit 30, according to an embodiment of the present invention. The buzzer driving system 1 is configured as a system independent of the buzzer 2 and is arranged separately therefrom. Accordingly, the buzzer driving system 1 can be directly applied to an existing buzzer 2 without requiring any modification to the structure of the buzzer 2.

According to an embodiment of the present invention, the driving unit 10 is electrically connected to the buzzer 2 and is configured to receive the audio signal S corresponding to the buzzer 2, and to output a driving voltage D to the buzzer 2 based on the audio signal S, such that the buzzer 2 emits sound based on the driving voltage D. The audio signal S may be a digital or analog signal originating from an external device. In one embodiment, the audio signal S is a digital signal, such as a pulse width modulation (PWM) signal. In another embodiment, the audio signal S is an analog signal, such as a human voice audio signal, a speech audio signal, or a music audio signal. In some embodiments, the analog signal may include an audio signal resulting from audio signal processing applied to a human voice, speech, or music signal, wherein the processing may include attenuation or enhancement of specific frequency bands. In some embodiments, the analog signal may be generated by applying a low-pass filter to a digital signal, such as a PWM signal. The above descriptions are provided merely as examples and are not intended to limit the scope of protection of the present invention.

Referring further to FIG. 2, the driving unit 10 comprises a gain control circuit 11. The gain control circuit 11 adjusts the gain of the audio signal S based on a gain factor, and the driving unit 10 outputs the driving voltage D based on the audio signal S after the gain adjustment. The gain factor is set based on an estimated gain, and the gain control circuit 11 may dynamically adjust the gain factor based on the estimated gain.

The gain control circuit 11 may include an amplifier 111, at least one input resistor Rin, and at least one feedback resistor Rf. In FIG. 2, the gain control circuit 11 is illustrated as including one input resistor Rin and one feedback resistor Rf; however, the number of the at least one input resistor Rin and the at least one feedback resistor Rf is not limited to this embodiment. The input resistor Rin is connected in series to the inverting input terminal of the amplifier 111, and the feedback resistor Rf is connected in series between the inverting input terminal and the output terminal of the amplifier 111. A voltage reference ref is applied to the non-inverting input terminal of the amplifier 111. The gain factor of the gain control circuit 11 corresponds to the resistance ratio between the at least one feedback resistor Rf and the at least one input resistor Rin, which, in this embodiment, is the ratio between Rf and Rin. The amplifier 111 adjusts the gain of the audio signal S based on the gain factor and outputs the adjusted audio signal S through the output terminal. In other words, the gain control circuit 11 may control the gain by adjusting the resistance values of each feedback resistor Rf and each input resistor Rin, and each input resistor Rin and each feedback resistor Rf may be variable resistors.

In the embodiment illustrated in FIG. 2, the driving unit 10 can include a first-stage amplifier 12 and a second-stage amplifier 13. The first-stage amplifier 12 includes a first input terminal, a second input terminal, and an output terminal. The first input terminal of the first-stage amplifier 12 is electrically connected to the output terminal of the amplifier 111 to receive the audio signal S after gain adjustment. The second input terminal of the first-stage amplifier 12 is electrically connected to the voltage reference ref, and the output terminal of the first-stage amplifier 12 is electrically connected to a non-inverting input terminal of the buzzer 2. The first-stage amplifier 12 amplifies the audio signal S and outputs a first voltage via its output terminal.

The second-stage amplifier 13 includes a first input terminal, a second input terminal, and an output terminal. The first input terminal of the second-stage amplifier 13 is electrically connected to the output terminal of the first-stage amplifier 12 to receive the first voltage. The second input terminal of the second-stage amplifier 13 is electrically connected to a voltage reference ref, and the output terminal of the second-stage amplifier 13 is electrically connected to a negative terminal of the buzzer 2. After amplifying the first voltage, the second-stage amplifier 13 outputs a second voltage through its output terminal.

The driving voltage D corresponds to the difference between the first voltage and the second voltage. The driving unit 10 outputs the driving voltage D to the buzzer 2 through the first-stage amplifier 12 and the second-stage amplifier 13 to drive the buzzer 2 to emit a sound corresponding to the driving voltage D.

The boost unit 20 is electrically connected to an external input power source and the driving unit 10. The boost unit 20 receives an input voltage VDD supplied by the input power source and boosts the input voltage VDD to generate a working voltage VOUT. The working voltage VOUT is then output to the driving unit 10 to supply power thereto and maintain its operation. The working voltage VOUT can also raise the voltage level of the output stage of the driving unit 10. The voltage value of the working voltage VOUT output from the boost unit 20 can be preset to a fixed value based on the operational requirements of the driving unit 10 and the buzzer 2, while the voltage value of the input voltage VDD can fluctuate depending on the condition of the input power source.

For example, the working voltage VOUT can be preset to 18V, and the input voltage VDD can be within a range of 2V to 5V. Regardless of fluctuations in the voltage value of the input voltage VDD, the boost unit 20 boosts the input voltage VDD to the preset 18V and outputs the boosted input voltage VDD to the driving unit 10, thereby ensuring the stable operation of the driving unit 10 without being affected by variations in the input voltage VDD.

The gain estimation unit 30 is electrically connected to an external input power source, the driving unit 10, and the boost unit 20, and receives the input voltage VDD from the input power source and the operating voltage VOUT from the boost unit 20. The gain estimation unit 30 is preset with a plurality of stepwise voltages generated based on the operating voltage VOUT. The gain estimation unit 30 detects the voltage value of the input voltage VDD and generates an estimated gain based on the comparison between the input voltage VDD and the stepwise voltages. The gain estimation unit 30 then generates a gain signal M to the driving unit 10 based on the estimated gain to control the gain control circuit 11 to adjust the gain factor corresponding to the estimated gain. The gain estimation unit 30 controls the gain control circuit 11 via the gain signal M to adjust the resistance ratio of the at least one feedback resistor Rf and the at least one input resistor Rin corresponding to the estimated gain. Alternatively, upon receiving the gain signal M, the gain control circuit 11 adjusts the resistance values of the at least one feedback resistor Rf and the at least one input resistor Rin based on the estimated gain.

On the other hand, after the boost unit 20 boosts the input voltage VDD to generate the operating voltage VOUT, the boost unit 20 transmits a ready signal R to the gain estimation unit 30, allowing the gain estimation unit 30 to confirm that the boosting operation has been completed and that subsequent gain estimation based on the boost ratio can be performed.

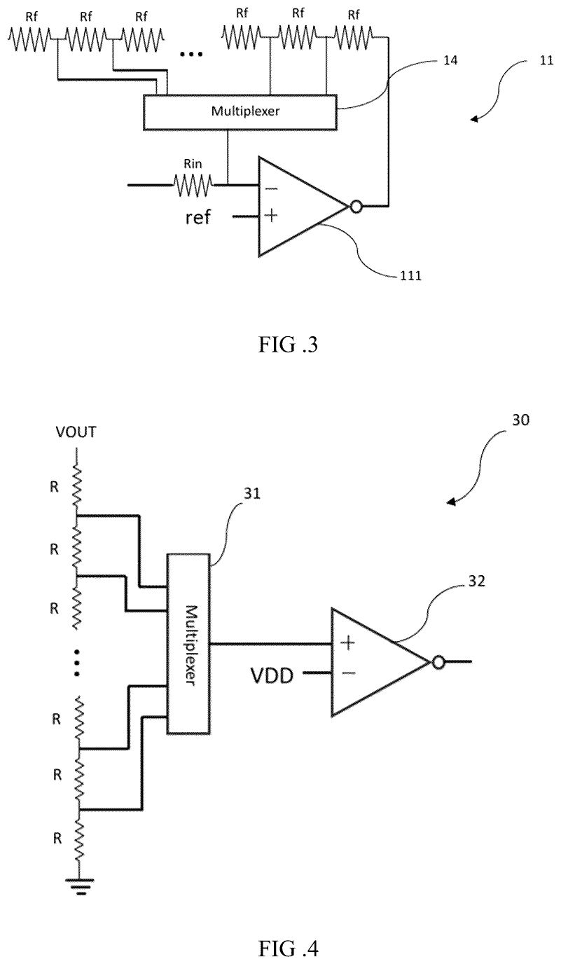

Referring further to FIG. 3, in an embodiment, the gain control circuit 11 comprises a multiplexer 14, a plurality of feedback resistors Rf, and an input resistor Rin. The multiplexer 14 is connected between the inverting input terminal and the output terminal of the amplifier 111. The plurality of feedback resistors Rf are connected in series between the multiplexer 14 and the output terminal of the amplifier 111. The multiplexer 14 includes a plurality of input terminals, each connected between two serially connected feedback resistors Rf. The gain control circuit 11 can adjust the number of feedback resistors Rf that are connected between the inverting input terminal and the output terminal of the amplifier 111 via the multiplexer 14, thereby changing the resistance ratio between the connected feedback resistors Rf and the input resistor Rin, and thus adjusting the gain factor of the amplifier 111.

Conversely, in other embodiments, the gain control circuit 11 may also comprise another multiplexer 14, a plurality of input resistors Rin, and a feedback resistor Rf. The multiplexer 14 adjusts the number of input resistors Rin connected to the inverting input terminal of the amplifier 111, thereby changing the resistance ratio between the feedback resistor Rf and the connected input resistors Rin, and thus adjusting the gain factor of the amplifier 111.

In addition, in other embodiments, the gain control circuit 11 may also comprise two multiplexers 14, a plurality of feedback resistors Rf, and a plurality of input resistors Rin. The two multiplexers 14 respectively adjust the number of feedback resistors Rf connected between the inverting input terminal and the output terminal of the amplifier 111, and the number of input resistors Rin connected to the inverting input terminal of the amplifier 111. In this way, the resistance ratio between the connected feedback resistors Rf and the connected input resistors Rin can be varied to flexibly adjust the gain factor.

In the embodiment shown in FIG. 4, the gain estimation unit 30 comprises a plurality of voltage divider resistors R, a multiplexer 31, and a comparator 32. The plurality of voltage divider resistors R are connected in series, with one end of the series-connected resistors connected to the boost unit 20 to receive the operating voltage VOUT, and the other end grounded. Each voltage divider resistor R divides the operating voltage VOUT to generate a plurality of stepwise voltages. The plurality of input terminals of the multiplexer 31 are connected to the plurality of voltage divider resistors R, where each input terminal is electrically connected between two voltage divider resistors R. Accordingly, each input terminal of the multiplexer 31 can receive one of the stepwise voltages through the corresponding voltage divider resistors R. In other words, the multiplexer 31 receives the plurality of stepwise voltages through its plurality of input terminals. A non-inverting input terminal of the comparator 32 is connected to an output terminal of the multiplexer 31 to receive the stepwise voltage output by the multiplexer 31. An inverting input terminal of the comparator 32 may be connected to the boost unit 20 to receive the input voltage VDD. The comparator 32 compares each of the stepwise voltages with the input voltage VDD, and the gain estimation unit 30 calculates and generates the estimated gain based on the comparison results of the comparator 32.

When the comparator 32 compares each of the stepwise voltages with the input voltage VDD, the gain estimation unit 30, through the comparator 32, determines the stepwise voltage whose voltage value is not less than the input voltage VDD and is closest to the input voltage VDD. The estimated gain is then calculated based on a ratio between the operating voltage VOUT and the identified stepwise voltage.

The buzzer 2 may be a piezoelectric buzzer, whose main structure comprises a piezoelectric element, a metal plate, and a housing. The piezoelectric element may be made of a piezoelectric ceramic material. When subjected to a voltage, the piezoelectric element deforms due to the piezoelectric effect, thereby driving the metal plate to vibrate and generate sound. The housing not only encloses the piezoelectric element and the metal plate but also forms a resonant cavity for the piezoelectric element and the metal plate.

Compared to conventional speakers, the buzzer 2 has advantages such as low power consumption, loud sound output, small size, low cost, and high durability. Due to its structural and material characteristics, the buzzer 2 also exhibits greater durability and stability under extreme environments such as high temperature or humidity. In contrast to speakers, which are more prone to damage and are more expensive, the buzzer 2 offers irreplaceable advantages.

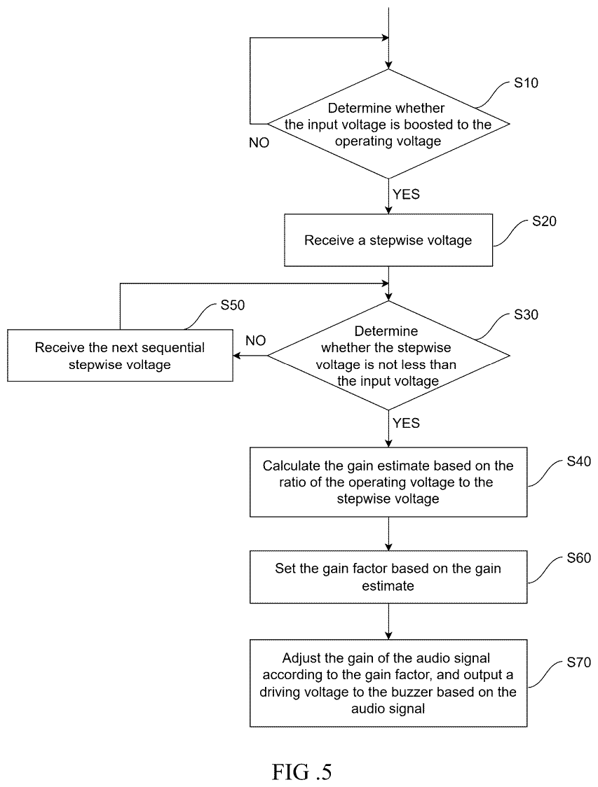

Referring to FIG. 5, a driving method for a buzzer is applied to the buzzer 2 and can be executed by the buzzer driving system 1, according to an embodiment of the present invention. Steps S10 to S50 may be performed by the gain estimation unit 30, and steps S60 and S70 may be performed by the driving unit 10. The driving method for the buzzer includes the following steps.

In step S10, it is determined whether an input voltage VDD has been boosted to an operating voltage VOUT. Specifically, the gain estimation unit 30 determines whether the boosting operation has been completed based on a ready signal R output from the boost unit 20. If so, subsequent gain estimation can be performed based on the resulting operating voltage VOUT.

In step S20, when it is determined that the input voltage VDD has been boosted to the operating voltage VOUT, one of a plurality of stepwise voltages is received. Specifically, the multiplexer 31 outputs one of the stepwise voltages to the comparator 32.

In step S30, the input voltage VDD is compared with the selected stepwise voltage to determine whether the selected stepwise voltage is not less than the input voltage VDD. Specifically, the comparator 32 determines whether the stepwise voltage output by the multiplexer 31 is not less than the input voltage VDD.

In step S40, when it is determined that the selected stepwise voltage is not less than the input voltage VDD, an estimated gain is calculated based on a ratio of the operating voltage VOUT to the selected stepwise voltage, and the comparison between the input voltage VDD and the remaining stepwise voltages is terminated.

In step S50, when it is determined that the selected stepwise voltage is less than the input voltage VDD, a next stepwise voltage among the plurality of stepwise voltages is received. The multiplexer 31 outputs the next stepwise voltage to the comparator 32. During the execution of step S30 and repeated execution of step S50, the multiplexer 31 sequentially outputs the stepwise voltages in ascending order of voltage level.

In step S60, a gain factor is set based on the estimated gain.

In step S70, the gain of an audio signal S is adjusted based on the gain factor, and a driving voltage D is output to the buzzer 2 based on the audio signal S. Specifically, a first voltage and a second voltage are generated based on the audio signal S, and the driving voltage D corresponds to the voltage difference between the first voltage and the second voltage.

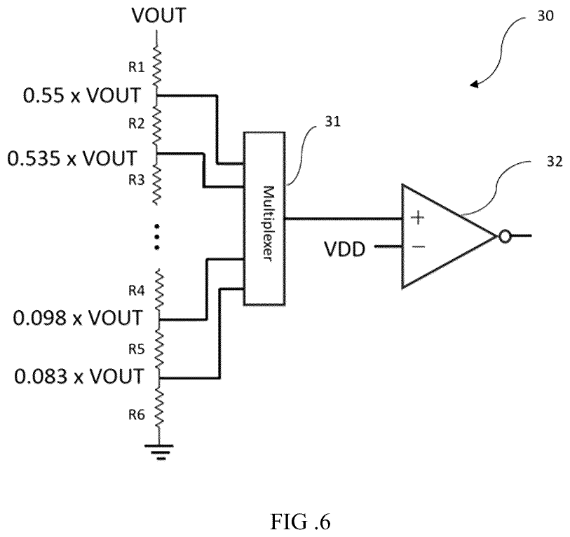

Referring to FIG. 6, an example is provided in which the multiplexer 31 is a 5-bit multiplexer, and the plurality of voltage divider resistors R includes 33 voltage divider resistors R, thereby generating 32 levels of stepwise voltages. The plurality of voltage divider resistors R includes, for example, a first voltage divider resistor R1, a second voltage divider resistor R2, a third voltage divider resistor R3, a fourth voltage divider resistor R4, a fifth voltage divider resistor R5, and a sixth voltage divider resistor R6, and so on. By setting the resistance values of the voltage divider resistors R, the stepwise voltage generated between the first voltage divider resistor R1 and the second voltage divider resistor R2 is 0.55 times the working voltage VOUT. Each subsequent stepwise voltage differs from the previous one by 0.015 times the working voltage VOUT. Accordingly, the stepwise voltage between the second and third voltage divider resistors R2 and R3 is 0.535 times the working voltage VOUT; the stepwise voltage between the fourth and fifth resistors R4 and R5 is 0.098 times the working voltage VOUT; and the stepwise voltage between the fifth and sixth resistors R5 and R6 is 0.083 times the working voltage VOUT. Further details are omitted herein for brevity.

When the working voltage VOUT is 18 V and the input voltage VDD is 2.4 V, in step S20, the multiplexer 31 first outputs the stepwise voltage with the lowest voltage value to the comparator 32, i.e., the stepwise voltage generated between the fifth voltage divider resistor R5 and the sixth voltage divider resistor R6 is output to the comparator 32. In steps S30 and S50, since this stepwise voltage is 1.494 V (0.083 times the working voltage VOUT), the comparator 32 determines that the stepwise voltage is less than the input voltage VDD. Then, the multiplexer 31 outputs the next stepwise voltage to the comparator 32, i.e., the stepwise voltage generated between the fourth voltage divider resistor R4 and the fifth voltage divider resistor R5. The next stepwise voltage is 1.764 V (0.098 times the working voltage VOUT), and again the comparator 32 determines that this stepwise voltage is less than the input voltage VDD. The multiplexer 31 then continues to output the following stepwise voltages in sequence.

When the multiplexer 31 outputs a stepwise voltage of 2.574 V (i.e., 0.143 times the working voltage VOUT) to the comparator 32, the comparator 32 determines that the stepwise voltage is greater than the input voltage VDD. Then, the gain detection unit 30 calculates the estimated gain based on the ratio between the working voltage VOUT and this stepwise voltage. Specifically, by calculating the ratio between 1×VOUT and 0.143×VOUT, the resulting estimated gain is determined to be 6.99. This estimated gain is close to the actual gain of 7.5, which corresponds to the ratio between the working voltage VOUT and the input voltage VDD.

It should be noted that the above description is provided by way of example only and is not intended to limit the implementations of the plurality of stepwise voltages or the gain estimation unit 30.

In addition, the accuracy of the detected estimated gain relative to the actual gain is positively correlated with the number of stepwise voltages. The greater the number of stepwise voltages, the smaller the voltage difference between each pair of adjacent stepwise voltages. As a result, when the comparator 32 determines that one of the stepwise voltages is greater than the input voltage VDD, the voltage difference between that stepwise voltage and the input voltage VDD is reduced. Consequently, the gain estimation unit 30 can calculate a more accurate estimated gain. Therefore, the number of stepwise voltages can be configured based on an accuracy requirement. The number of stepwise voltages increases as the accuracy requirement increases. The accuracy requirement refers to the degree to which the estimated gain approximates the actual gain. Furthermore, the voltage difference between two adjacent stepwise voltages may be uniform or non-uniform, and the scope of the present invention is not limited to the example described above.

In summary, the buzzer driving system 1 and the corresponding method described above can generate the driving voltage D based on the audio signal S in either analog or digital form. As such, the operation of the buzzer 2 is not limited by the signal format and can benefit from the characteristics of analog signals, enabling the buzzer 2 to produce sound with greater tonal detail instead of a single tone. This allows the buzzer 2 to deliver sound quality comparable to that of a typical speaker, while still retaining advantages such as high volume output, low component cost, and high durability.

In addition, the buzzer driving system 1 is capable of detecting the step-up ratio by which the boost unit 20 converts the input voltage VDD into the operating voltage VOUT, according to the embodiments of the present invention. Through the automatic gain estimation mechanism based on the step-up ratio, the system can adapt to fluctuations in the input voltage VDD and accordingly adjust the gain factor for the audio signal S. This allows the driving unit 10 to amplify the audio signal S with the appropriate gain factor, thereby increasing the volume of the sound generated by the buzzer 2 based on the driving voltage D. At the same time, it prevents distortion of the audio signal S when the volume is increased, achieving the goal of preserving the original audio details and enhancing sound quality.

The present invention has been disclosed herein by way of exemplary embodiments. However, it will be understood by those skilled in the art that these embodiments are provided for illustrative purposes only and are not intended to limit the scope of the claimed invention. Any modifications or substitutions that are equivalent or have a substantially equivalent effect to the embodiments described above should be interpreted as falling within the spirit or scope of the present invention. Accordingly, the scope of protection for the present invention shall be defined by the following claims.

What is claimed is:

1. A buzzer driving system electrically connected to a buzzer, comprising:
a driving unit comprising a gain control circuit and configured to adjust the gain of an audio signal based on a gain factor determined by the gain control circuit, and to output a driving voltage to the buzzer based on the adjusted audio signal;
a boost unit electrically connected to the driving unit and configured to boost an input voltage to generate a working voltage to the driving unit; and
a gain estimation unit electrically connected to both the driving unit and the boost unit, and configured to generate a plurality of stepwise voltages based on the working voltage and to sequentially compare the input voltage with each of the stepwise voltages to produce an estimated gain;
wherein the gain factor used by the gain control circuit is determined based on the estimated gain.

2. The buzzer driving system of claim 1, wherein the gain estimation unit comprises a comparator having a non-inverting input terminal configured to receive each of the stepwise voltages and an inverting input terminal configured to receive the input voltage, and the comparator is configured to compare each of the stepwise voltages with the input voltage to generate the estimated gain.

3. The buzzer driving system of claim 2, wherein the gain estimation unit further comprises a plurality of voltage-dividing resistors and a multiplexer, the voltage-dividing resistors being connected in series between the working voltage and ground to generate the stepwise voltages, and
the multiplexer having a plurality of input terminals respectively connected between pairs of the voltage-dividing resistors, and an output terminal connected to the non-inverting input terminal of the comparator for selectively outputting each of the stepwise voltages to the comparator.

4. The buzzer driving system of claim 3, wherein the gain estimation unit is configured to determine, among the stepwise voltages, a voltage that is not less than and closest to the input voltage, and to calculate the estimated gain based on a voltage division ratio of the working voltage to the determined stepwise voltage.

5. The buzzer driving system of claim 4, wherein the multiplexer is configured to sequentially output the stepwise voltages to the comparator in an order from lowest to highest voltage, and when the comparator determines that one of the stepwise voltages is greater than the input voltage, the gain estimation unit stops the comparison.

6. The buzzer driving system of claim 1, wherein the gain control circuit comprises an amplifier connected to at least one input resistor and at least one feedback resistor, and the gain control circuit is configured to adjust a resistance ratio between the at least one feedback resistor and the at least one input resistor based on the estimated gain to control the gain factor.

7. A method for driving a buzzer, comprising:
determining whether an input voltage has been boosted to a working voltage;
sequentially comparing the input voltage with a plurality of stepwise voltages to generate an estimated gain when the input voltage has been boosted to the working voltage;
setting a gain factor based on the estimated gain;
adjusting the gain of an audio signal based on the gain factor; and
outputting a driving voltage to the buzzer based on the adjusted audio signal.

8. The method of claim 7, wherein the sequentially comparing step comprises:
comparing each of the stepwise voltages with the input voltage in an order from lowest to highest voltage;
comparing the input voltage with a next stepwise voltage when the current stepwise voltage is less than the input voltage; and
stopping the comparison between the input voltage and any remaining stepwise voltages when one of the stepwise voltages is determined to be not less than the input voltage.

9. The method of claim 7, wherein the estimated gain is calculated based on a voltage division ratio of the working voltage to a stepwise voltage that is not less than and closest to the input voltage.

10. The method of claim 7, wherein the number of the stepwise voltages is positively correlated with a required precision, and the number of the stepwise voltages increases as the required precision increases.
